(19) United States
(12) Patent Application Publication
(10) Pub. No.: US 2002/0094699 A1
(43) Pub. Date: Jul. 18, 2002

(54) Method for producing a metal oxide semiconductor field effect transistor

(76) Inventors: Mau-Phon Houng, Tainan (TW); Yeong-Her Wang, Tainan (TW); Zhen-Song Ya, Tou--Wu Shiang (TW)

Correspondence Address: J.C. Patents, Inc., 1340 Reynolds Ave., Suite 114, Irvine, CA, 92614, US

(21) Appl. No.: 09/760,183

(22) Filed: Jan. 12, 2001

(51) Int. Cl. H01L 21/337; H01L 21/331; H01L 21/8222; H01L 21/3205; H01L 21/4763; H01L 21/28; H01L 21/31; H01L 21/469

(52) U.S. Cl. 438/779; 438/590; 438/191; 438/312; 438/604

(57) ABSTRACT

A method of fabricating a MOSEFT device, which is suitable for fabricating an III-V group semiconductor device. A substrate comprises a buffer layer and a channel layer, wherein silicon oxide is formed on the channel layer by a liquid phase deposition method (LPD) to control the parameters of growth solution. A silicon oxide insulating layer that is formed on the channel layer has a thickness of approximately 40 Å, wherein the silicon oxide insulating layer is used as a gate oxide layer. A source, a drain and a gate are formed on the gate oxide layer. The LPD process is performed in a temperature range from room temperature to 60° C. Thus, the low temperature of the LPD technique will not lead to a negative heat effect on other fabrications or on the wafer, therefore the low temperature will not cause thermal stress, dopant redistribution, dopant diffusion or material interaction, for example.

### BACKGROUND OF THE INVENTION

1. Field of Invention

The present invention relates generally to a method of fabricating a metal oxide semiconductor field effect transistor (MOSFET). More particularly, the present invention relates to a method of fabricating a GaAs MOSFET.

2. Description of the Related Art

In general, the elements of the III-V group that are used for fabricating a MOSFET device, for example, a gallium arsenide wafer, have high carrier mobility and a high energy gap. Therefore these elements are used in a large amounts of devices for high frequency micro-communication devices.

However, the evaporation of those elements in the V group are very severe when a device is subjected to high temperatures. Therefore, a low temperature method of fabricating an III-V group semiconductor device is very important. A thin film transistor (TFT) or solar cells are used on many applications because the thin oxide layer can improve the physical characteristics of a device and its driving ability. A lot of research efforts are dedicated to the technology of developing a better quality, more stable and thinner silicon dioxide insulating layer on a gallium arsenate chip.

A silicon dioxide insulating layer is usually formed by chemical vapor deposition (CVD) or thermal oxidation. To form a silicon dioxide insulating layer by CVD or thermal oxidation, a vacuum facility is needed and a high temperature process is necessary. However, once the temperature reaches several hundred degrees, it produces a heat effect, which negatively affects other processes or wafers, causing, for example, thermal stress, dopant redistribution, dopant diffusion or material interaction.

Furthermore, when using CVD or thermal oxidation to form a silicon dioxide insulating layer and when handling a large-area wafer, many difficulties exist, and the process is complicated and expensive.

### SUMMARY OF INVENTION

It is therefore an object of the present invention to provide a method for fabricating a MOSEFT in which a low temperature is required to form an insulating layer. Thus, the temperature will not lead to a negative heat effect on other processes or wafers or cause thermal stress, dopant redistribution, dopant diffusion or material interaction.

It is another object of the present invention to use a liquid phase deposition (LPD) method to control the temperature range from room temperature to 60° C. The thickness of the silicon dioxide insulating layer is very thin and is about 40 Å. The purpose of this thin insulating layer is to improve the quality and the driving ability of the device.

It is another object of the present invention to provide a process for fabricating a MOSEFT. A substrate on which a buffer layer and a channel layer are formed is provided. A silicon dioxide insulating layer is deposited on the channel layer by using a LPD method in order to control the doping concentration of the growth solution. A silicon dioxide insulating layer with a thickness of about 40 Å is formed on the channel layer and is used as a gate oxide layer on the channel layer. A source/drain electrode is formed on the gate oxide layer by annealing process. The source/drain electrode will have good ohmic contact with the substrate. The sequence of forming the gate oxide layer and the source/drain electrodes can be interchanged to increase the flexibility of the process integration.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic diagram of an apparatus used for growing silicon dioxide according to this invention;

FIG. 2 is a process flow diagram for growing silicon dioxide according to this invention;

FIG. 3 to FIG. 5 are schematic cross-sectional views of a MOSEFT in a fabrication process according to this invention;

FIG. 6A is a graph of capacitance versus voltage for a silicon dioxide layer with a thickness of 35 Å that is measured from the MOS capacitor structure formed by a LPD method;

FIG. 6B is a graph of current versus voltage for a silicon dioxide layer with a thickness of about 70 Å;

FIG. 7A is a graph of drain current versus voltage for an oxide layer with a thickness of 165 Å used as a gate oxide layer;

FIG. 7B is a normalized transconductance graph of drain current versus voltage;

FIG. 8A is a transfer curve graph of drain current versus voltage for an oxide layer with a thickness of 40 Å that is used as a gate oxide layer;

FIG. 8B is a normalized transconductance graph of drain current versus voltage;

FIG. 9 is a graph of transconductance versus thickness of the gate oxide layer;

FIG. 10 is a graph of device operating versus the thickness of the gate oxide layer.

### DESCRIPTION OF THE PREFERRED EMBODIMENT

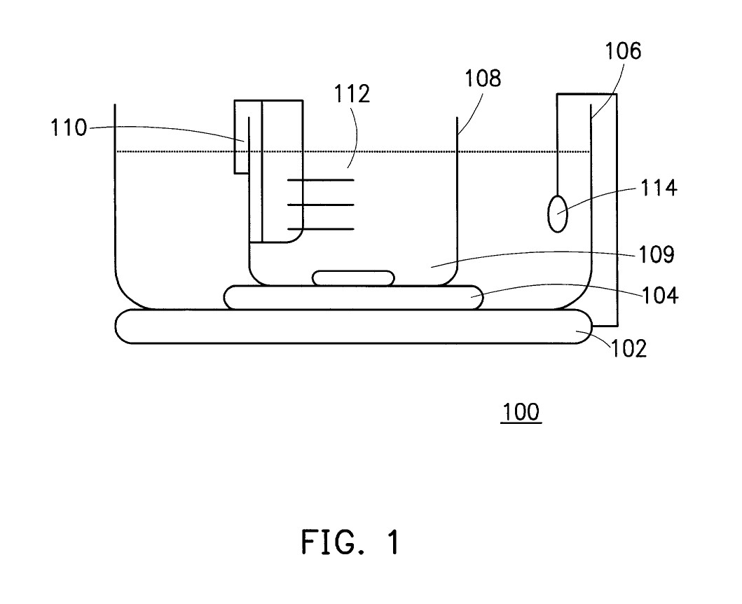

Recent research has shown that adding a little fluorine into silicon dioxide can improve the characteristics of silicon dioxide. Because the binding energy of silicon-fluorine is 5.8 eV, which is greater than a binding energy of 4.5 eV of silicon-oxygen in a pure silicon dioxide, silicon-fluorine can increase radiation hardness ability. Adding a little fluorine can also enhance the breakdown voltage and the breakdown field. The grown LPD-SiO₂ of the present invention is an oxide layer that contains less than 5 at. % of fluorine, and one advantage of the present invention is the omission of an extra doping process. Therefore, the present invention provides a simple and economical process. The presence of fluorine not only decreases the dielectric constant to approximately 3.5, but it also has a low reflection coefficient. The value 3.5 is also less than the value of 3.9 of the silicon oxide in a thermal oxidation process. Referring to FIG. 1, one preferred example of the SiO₂ growing system of the present invention is provided. The present invention provides a system of forming a silicon oxide insulating layer on a GaAs substrate by a LPD method from room temperature to 60° C. A system of growing SiO₂ 100 comprises a heater 102 to control the temperature, a magnetic stirrer 104, a large-size water container 106, a small-size container 108 that contains silicon dioxide growth solution 109 and a wafer holder 110. The wafer holder 110 is on the container 108, and the holder fixes several wafers 112 in place. These wafers 112 are then immersed in the growth solution 109 to grow the silicon dioxide insulating layer. The heater 102 further comprises a temperature sensor 114. The sensor 114 is used to detect the water temperature inside the container 106. To control the temperature of the growth solution 109 inside the container 108, the heater 102 uses a bath heating method to control the temperature and maintain it at about 60° C.

The process of fabricating the silicon dioxide growth solution 109 comprises the following steps 3.09M of H₂SiF₆ is added with the excess SiO₂.H₂0 power and stirred for 15 hours until the SiO₂.H₂O dissolves and reaches a saturated status in the H₂SiF₆ solution. The saturated solution is filtrated by a 0.1 m filter paper to have a clear solution of H₂SiF₆. The mixture is diluted to a value of 0.4M by using a deionized water method. The diluted mixture is placed into a thermostat of 60° C., and after stirring the mixture for 50 minutes, it is stabilized for 10 minutes.

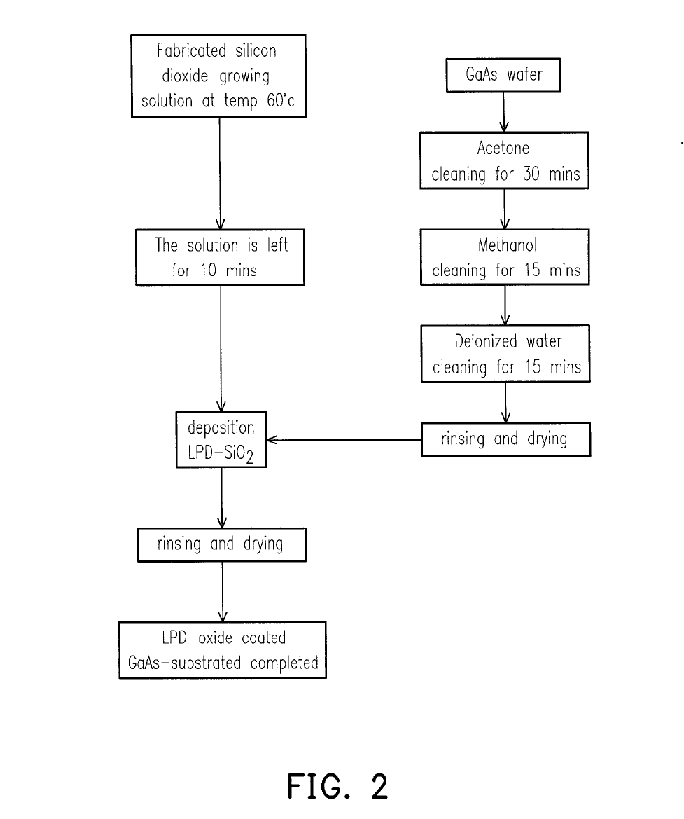

Referring to FIG. 2, the flow chart shows a process of growing a silicon dioxide insulating layer comprising the following steps: immersing the GaAs wafers 112 in an acetone solution and then cleaning the wafers 112 in an ultrasonic vibrator for 30 minutes; immersing the wafers in a methol solution and then cleaning the wafers in the ultrasonic vibrator for 15 minutes; cleaning the wafers in deionized water and then washing them in the ultrasonic vibrator for 10 minutes; cleaning the wafers in deionising water for 5 minutes; and drying the GaAs wafers by using nitrogen gas, thus completing the cleaning process of the wafers. Next, the mixture of silicon dioxide growth solution 109 is added into the container 108 in the silicon dioxide growth system 100 for 10 minutes without stirring. The wafers 112 are fixed by the wafer holder 110, and the wafers 112 are immersed in the silicon dioxide growth solution 109 to perform the LPD-SiO₂ process. Finally, the wafers 112 are cleaned with deionized water and dried with nitrogen gas. Thus, the process of forming a silicon dioxide insulating layer on the GaAs wafers 112 is completed.

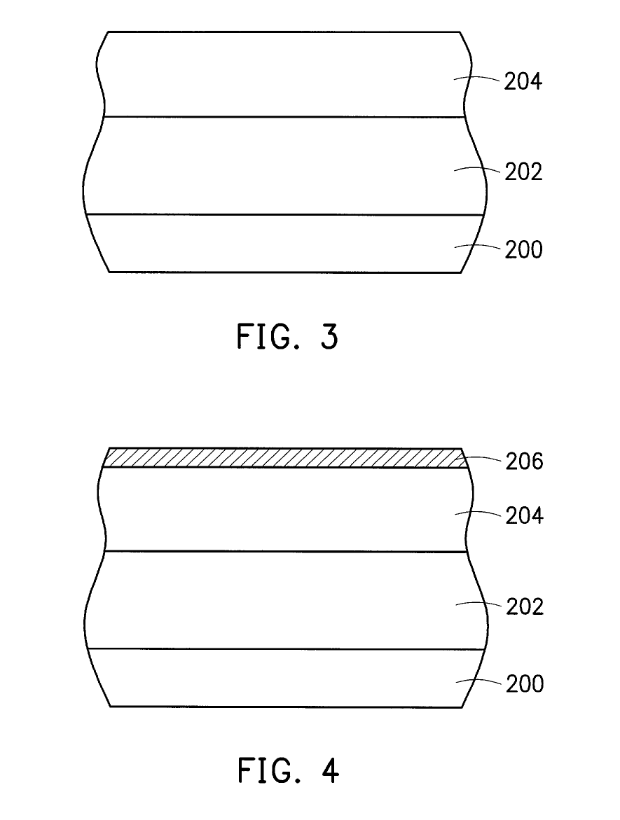

FIG. 3 to FIG. 5 are schematic, cross-sectional views showing the method of fabricating a MOSFET. As shown in FIG. 3, a substrate 200 is provided. The substrate 200 can be made of gallium arsenide, for example. A buffer layer 202 and a channel layer 204 are formed sequentially on the substrate 200. The buffer layer 202 can be a undoped gallium arsenide layer with a thickness of 5000 Å, for example. The channel layer 204 can be an n-type doped gallium arsenide with a thickness of 4000 Å. The concentration of the dopant of the channel 204 is about 5×10¹⁶cm⁻³.

Referring to FIG. 4, the substrate 200 is cleaned. The cleaning process comprises: immersing the substrate 200 in an acetone solution, and cleaning the substrate 200 in an ultrasonic vibrator for 30 minutes; immersing the substrate 200 in a methol solution for 15 minutes and cleaning it in the ultrasonic vibrator for 15 minutes; immersing the substrate 200 in the deionized water and cleaning it afterwards in an ultrasonic vibrator for 10 minutes; and cleaning the substrate 200 in the deionized water for 5 minutes and blow drying it with nitrogen gas. The cleaning process of the substrate 200 is thus completed. The gate oxide layer 206 is 40 Å thick, and the thickness can be controlled by the time of the LPD process.

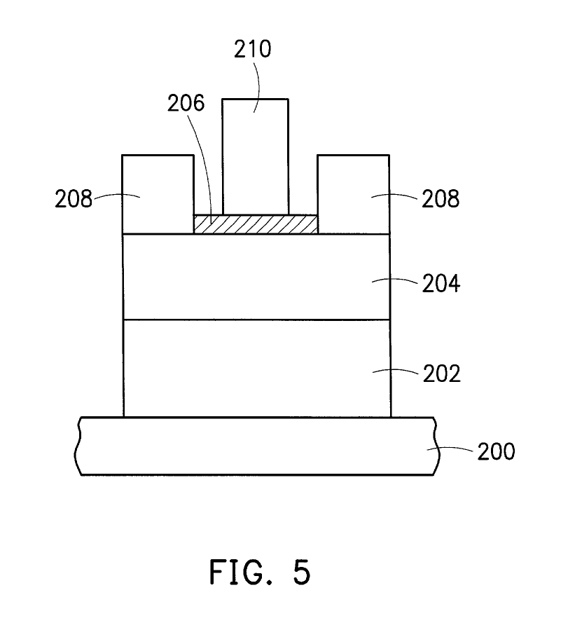

Referring to FIG. 5, the steps of defining an active region comprise: forming 1 μm thick photoresist layer on a portion of the gate oxide layer 206 by a spin coating method; and baking the photoresist layer for 20 minutes and using photolithography to define the active region.

A developer can be a diluted NaOH solution that is diluted 5 times with the deionized water. The developing time is 15 seconds. The volume ratio of the etching solution is ammonia:hydrogen peroxide:water=5:1:10. The etching time is 30 seconds, and a flat and island-shaped divider is formed as an active region.

A source/drain electrode position 208 is defined by photolithography and is etched using the diluted HF acid for 15 seconds to remove the gate oxide layer 206 on the source/drain electrode. The source/drain electrode is formed. The method that is used to form the source/drain electrode is similar to an evaporation deposition method to form a gold/nickel/germanium alloy. The source/drain electrode is made of Au/Ge/Ni alloy, and the thickness of the source/drain electrode is approximately 1800 Å. The process of forming an ohmic contact in the source/drain region is an alloy process. The step of this alloy process comprises the following steps: annealing the wafers in a nitrogen gas tubular tube at 400° C. and at 1 atmospheric pressure for 30 minutes or annealing the wafers in the tubular tube at a vacuum pressure from 1×10⁻⁵ torr to 2×10⁻⁵ torr and at a temperature of 400° C. for 30 minutes; then diffusing Ge from the source/drain electrode to the wafers to form a n⁺region (approximately 10¹⁹cm⁻³). A good conductive ohmic contact is thus formed.

Finally, a gate position 210 is defined. An evaporation method is used to form a 1000 Å thick gate 210. The gate 210 can be made of Au/Ge/Ni alloy or an alumium metal.

LPD-SiO₂ is formed on the exposed regions of the gate oxide layer 206 that are n-channel shaped on the top of the gate oxide layer 206 of the MOSFET. The highest temperature during this method of fabricating the MOSFET is the annealing temperature. This annealing process is performed at a temperature of 400° C. for 30 minutes to form the ohmic contact alloy in the source/drain electrode 208. During this annealing condition, the Ge diffuses from the source/drain electrode 208 to the substrate 200 to form the n⁺region. A specific contact resistance can be measured of a reading of 1×10^{-Ω/cm}⁻² by a TLM.

The condition of the annealing process can also density the gate oxide layer 206. Therefore, the annealing condition has a double effect in this method. The sequence of forming the gate oxide layer 206 and the source/drain electrode 208 can be interchanged to increase the flexibility of the process integration.

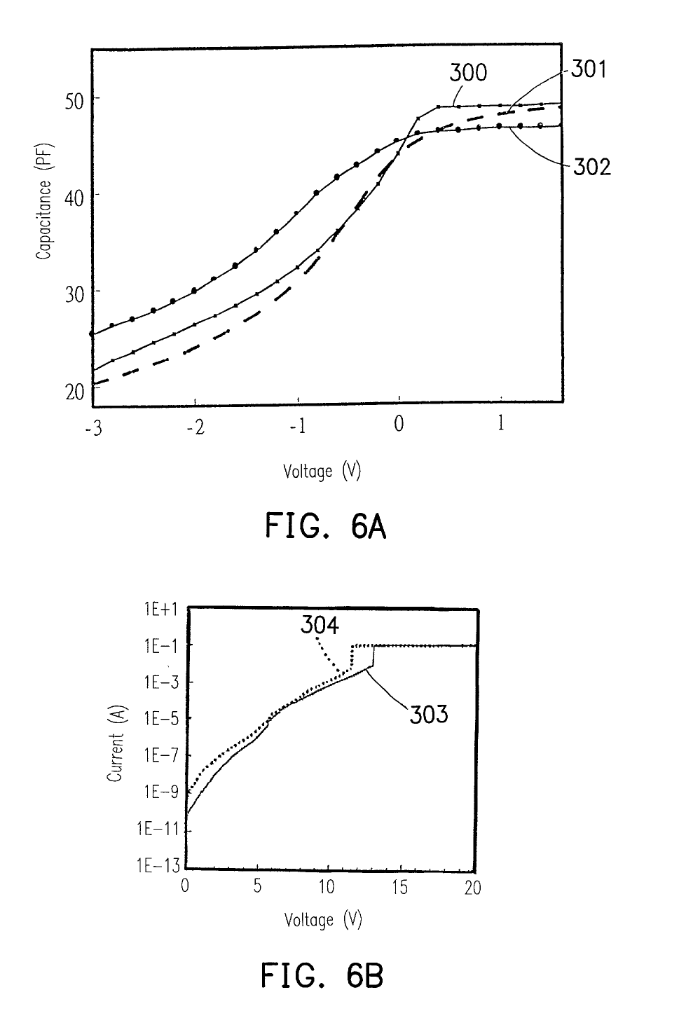

Referring to FIG. 6A, the graph illustrates the relationship between capacitance and voltage of a LPD-SiO₂ layer with a thickness of 35 Å in a MOS capacity structure. Because the thickness of the oxide layer is only 35 Å and the dopant concentration of the n-type wafers is 1.25×10⁻¹⁸cm³, there is a difference between pre-heat treatment and post-heat treatment.

The C-V curve 300 that is very close to the ideal C-V curve 301 indicates the C-V improvement by post-heat treatment, but the big gap between the ideal curve 301 and the curve 302 indicates the C-V degradation by pre-heat treatment. Because of the slightly high readings of the capacitance, the heat treatment can reduce the moisture in the oxide layer, so that the oxide layer can become dense. The thickness and refractive index of the LPD-SiO₂ can be measured by ellipsometer.

Because the tunneling current effect will reduce the readings of capacitance, the dielectric constant is reduced to 1.7, but when the thickness of the oxide layer is 70 Å, the reading of the dielectric constant will be 3.5 which is the same as the reading of the LPD-SiO₂.

Referring to FIG. 6B, I-V curves represent pre/post heat treatment effects on a LPD-SiO₂ layer with a thickness of 70 Å and with a gate area 1.16×10⁻⁴cm² and a dopant concentration of 1.25×10¹⁸cm⁻³ of an n-type wafer. The breakdown voltage of the preheat treatment curve 303 and the post-heat treatment curve 304 is almost the same. The breakdown voltage is approximately 17 MV/cm, because the process of fabricating the ohmic contact of the device is subjected to an annealing temperature of 400° C. for 30 minutes. Therefore the gate oxide layer will not be damaged.

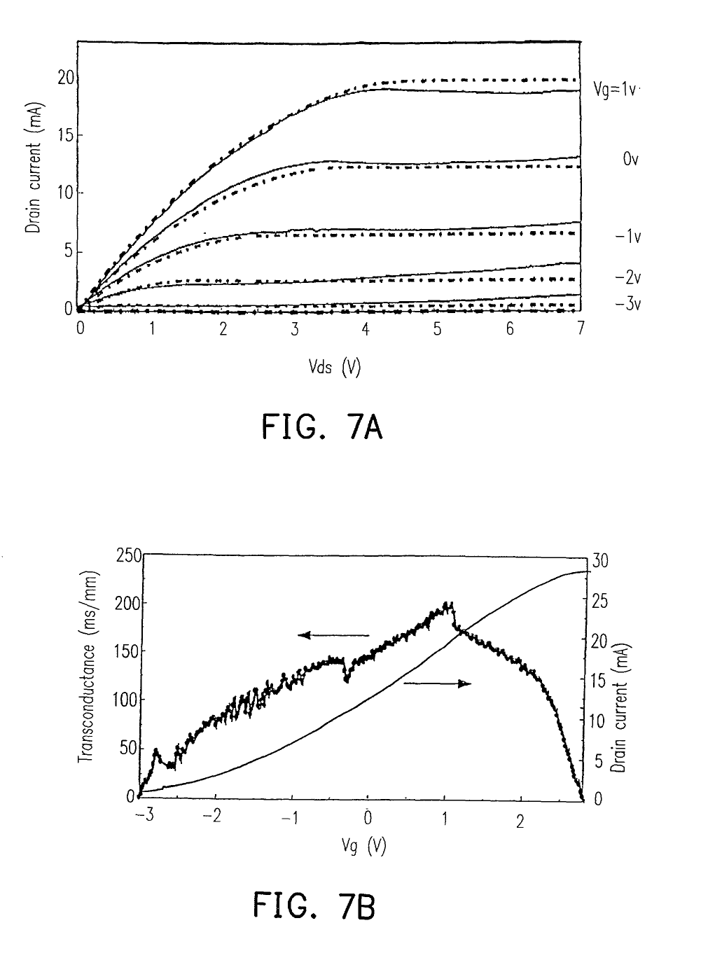

Referring to FIG. 7, I_{ds}-V_{ds} curves represent a LPD-SiO₂ layer with a thickness of 165 Å that is used as a gate oxide layer. The solid curve represents an experimental curve and the dashed curve represents a simulated curve. Under the experimental condition, the width of the gate oxide layer is 40 μm, its length is 8 μm and its thickness is 165 Å. The thickness of the channel layer is approximate 4000 Å. Because the channel does not have an inversion layer, a deep depletion occurs. Once the threshold voltage reaches 3.7V, the threshold voltage can be controlled by the thickness of the channel layer.

FIG. 7B illustrates the normalized transconductance of the device, and the largest reading can be up to 200 ms/mm.

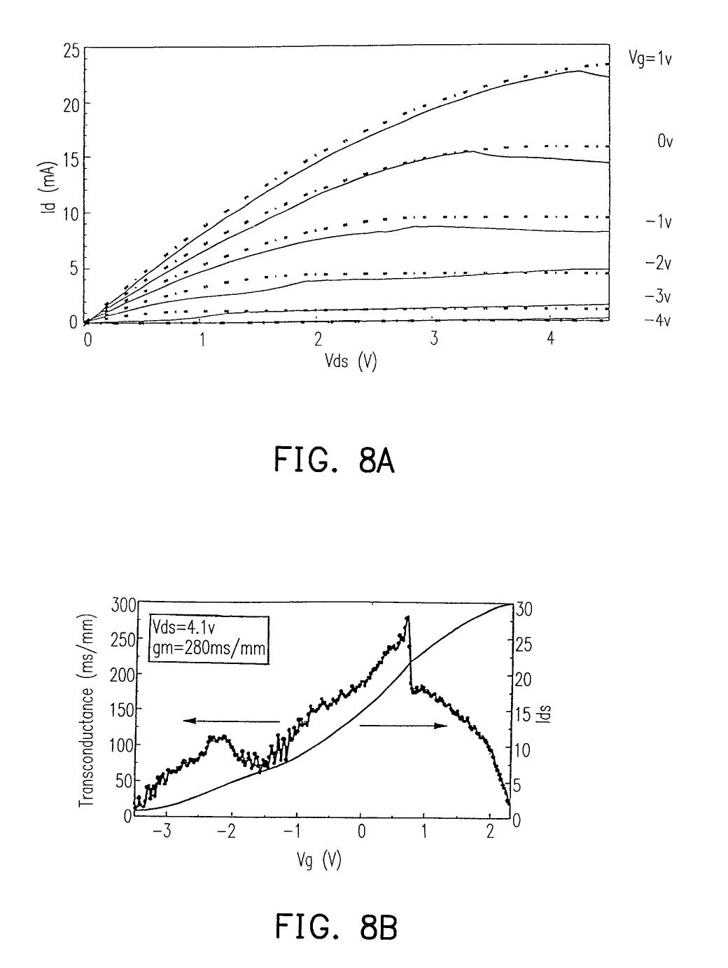

Referring FIG. 8A, I_{ds}-V_{ds} curves represent a LPD-SiO₂ layer with a thickness of 40 Å that is used as a gate oxide layer. The solid curve represents an experimental curve, and the dashed curve represents a simulated curve. Under the experimental condition, the width of the gate is 40 μm, its length is 8 μm and its thickness is 40 Å. FIG. 8B represents the readings of normalized transconductance, and the largest reading can be up to 280 ms/mm.

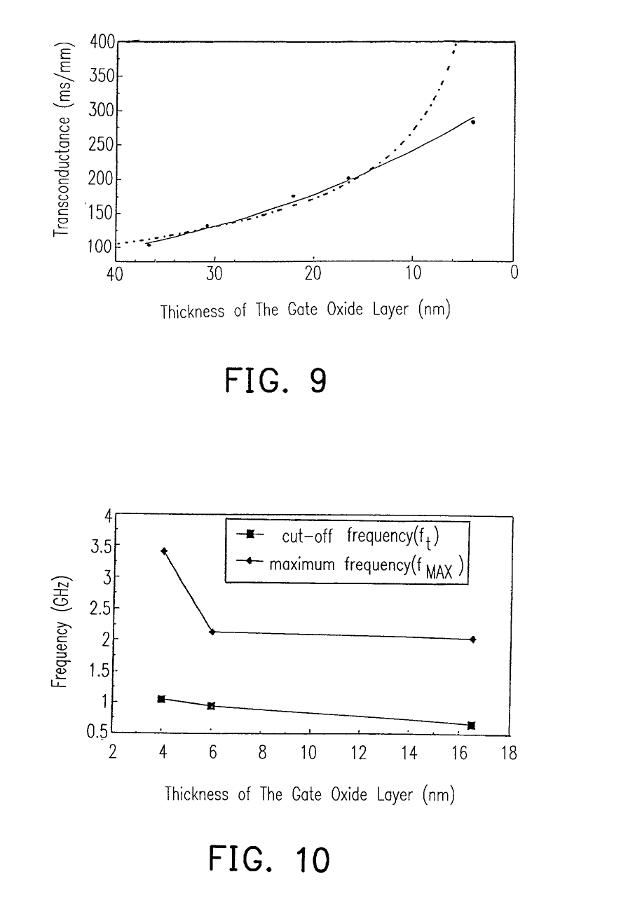

Referring to FIG. 9, a graph of transconductance versus thickness of the gate oxide layer is provided. The transconductance increases according to the decreasing thickness of the gate oxide layer. Therefore a thin gate oxide layer will increase the performance of the device.

Referring to FIG. 10, a graph of device operating fequency versus the thickness of the gate oxide layer is provided. The length of the channel is 12 μm. The bias voltage of the source/drain (V_{DS}) is 4V and the gate voltage (V_{G}) is 0.1V. The cut-off frequency (fₜ) that is measured by a network analyzer can reach 1.2 GHz, and the maximum frequency (f_{MAX}) can also reach 3.4 GHz. These readings are far larger than those of the conventional method for fabricating a MOSFET device. Therefore the present invention is suitable for use in communication devices.

In view of the foregoing, the present invention has the following advantages:

1. The annealing process of the present invention can allow heat to diffuse into the substrate to form an n⁺region, and can increase the density of the gate oxide layer to allow for a very thin gate oxide layer.

2. The sequence of forming the gate oxide layer and source/drain electrodes can be interchanged to increase the flexibility of the process' integration.

3. The present invention has a thin gate oxide layer, therefore high readings of transconductance are obtained and the quality of the device is enhanced.

4. The present invention can provide high values of fₜ=1.2 GHz and f_{MAX}=3.4 GHz that are far greater than the conventional method for fabricating a MOSFET device. Therefore the present invention is more suitable for use in communication devices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a MOSFET device, suitable for a GaAs MOSFET, the process comprising:
providing a substrate;
providing a buffer layer on the substrate;
providing a channel layer on the substrate;
forming a gate oxide layer on the channel layer by a LPD process;
defining an active region on the substrate;
forming a source electrode and a drain electrode on the substrate; and
forming a gate on the gate oxide layer.

2. The method of claim 1, wherein the buffer layer can be made of undoped GaAs.

3. The method of claim 1, wherein the channel layer can be made of n-type doped GaAs.

4. The method of claim 3, wherein the concentration of the n-type dopant is approximately 5×10¹⁶cm⁻³.

5. The method of claim 1, wherein the active region is defined by photolithography and is used to etch away a portion of the buffer layer and channel layer, thus forming an island-shaped divider as the active region.

6. The method of claim 1, wherein the steps of forming the source electrode and drain electrode comprises:
defining the positions of the source electrode and the drain electrode by a photo mask;
removing the gate oxide layer on the positions of the source electrode and the drain electrode; and
evaporating an Au/Ge/Ni alloy to form the source electrode and the drain electrode.

7. The method of claim 1, wherein the step of forming the source electrode and the drain electrode comprises an annealing process to form an ohmic contact in which the source electrode and the drain electrode has good ohmic contact with the substrate.

8. The method of claim 1, wherein the gate can be made of Au/Ge/Ni alloy or an alumium metal.

9. The method of claim 1, wherein the thickness of the gate is approximately 1000 Å.

10. A method of fabricating a MOSFET device, suitable for a GaAs MOSFET device, the method comprising:
providing a substrate;
providing a buffer layer on the substrate;
providing a channel layer on the substrate;
defining an active region on the substrate;
forming a source electrode and a drain electrode on the substrate;
forming a gate oxide layer on the channel layer by a LPD process; and
forming a gate on the gate oxide layer.

11. The method of claim 10, wherein the buffer layer can be made of undoped GaAs.

12. The method of claim 10, wherein the channel layer can be made of n-type doped GaAs.

13. The method of claim 12, wherein the concentration of the N-type dopant is 5×10¹⁶cm⁻³.

14. The method of claim 10, wherein the active region is defined using photolithography to etch away a portion of the buffer layer and channel layer, thus forming an island-shape divider as an active region.

15. The method of claim 10, wherein the step of forming the source electrode and the drain electrode comprises:
defining the positions of the source electrode and the drain electrode using a photomask; and
evaporating an Au/Ge/Ni alloy to form the source electrode and the drin electrode.

16. The method of claim 10, wherein the forming step comprises an annealing process to form an ohmic contact that allows good contact between the source electrode, the drain electrode and the substrate.

17. The method of claim 10, wherein the gate can be made of an Au/Ge/Ni alloy or an alumium metal.

18. The method of claim 10, wherein the thickness of the gate is 1000 Å.
